(19) United States
(12) Patent Application Publication
(10) Pub. No.: US 2026/0050008 A1
(43) Pub. Date: Feb. 19, 2026

(54) TEST HANDLER AND TEST METHODS FOR SEMICONDUCTOR PACKAGES

(71) Applicant: SEMES CO., LTD., Chungcheongnam-do (KR)

(72) Inventors: Harkryong KIM, Chungcheongnam-do (KR); Jongsung PARK, Chungcheongnam-do (KR)

(21) Appl. No.: 19/276,389

(22) Filed: Jul. 22, 2025

(30) Foreign Application Priority Data
Aug. 14, 2024 (KR) 10-2024-0109443

(51) Int. Cl. G01R 1/04; G01R 31/28

(52) U.S. Cl. CPC G01R 1/0466; G01R 31/2831

(57) ABSTRACT

The present invention relates to a test handler and a testing method for semiconductor packages capable of performing electrical inspection processes. The test handler may include a loader unit to pick up a semiconductor package from a first customer tray in which semiconductor packages to be tested are placed, or to place a tested semiconductor package into a second customer tray, a tester unit to test the semiconductor package loaded from the loader unit and to unload the tested semiconductor package back to the loader unit, and a shuttle unit installed to connect the loader unit and the tester unit, to transfer the semiconductor package to either the tester unit or the loader unit and to preheat or cool the semiconductor package during the transfer process.

### CROSS-REFERENCE TO RELATED PATENT APPLICATION

This application claims the benefit of Korean Patent Application No. 10-2024-0109443, filed on Aug. 14, 2024, in the Korean Intellectual Property Office, the disclosure of which is incorporated herein in its entirety by reference.

### BACKGROUND OF THE INVENTION

### 1. Field of the Disclosure

The present disclosure relates to a test handler and a test method for semiconductor packages, and more particularly, to a test handler and a test method for performing electrical inspection processes on semiconductor packages.

### 2. Description of the Related Art

In general, semiconductor devices can be formed on a silicon wafer, which is used as a semiconductor substrate, by repetitively performing a series of manufacturing processes. The semiconductor devices thus formed may be manufactured into semiconductor packages through dicing, bonding, and packaging processes.

The semiconductor packages manufactured as described above can be determined to be either non-defective or defective through electrical characteristic inspection. Such electrical inspection may employ a test handler for handling the semiconductor devices and a tester for inspecting the semiconductor packages.

Recently, as various types of semiconductor devices have been developed, there is an increasing demand for electrical inspection processes for the semiconductor devices that have been singulated through a dicing process, and accordingly, a growing need for inspection devices capable of performing such processes. For example, in the case of High Bandwidth Memory (HBM) devices formed on a wafer, an electrical inspection process may be required after the devices have been singulated by the dicing process.

### SUMMARY OF THE INVENTION

The present disclosure has been made in order to resolve various problems including those described above, and its object is to provide a test handler and a test method for semiconductor packages that are capable of performing electrical inspection processes for High Bandwidth Memory (HBM) devices. However, such objects are merely exemplary and do not limit the scope of the present disclosure.

According to one embodiment of the present disclosure, a test handler is provided. The test handler may include a loader unit to pick up a semiconductor package from a first customer tray in which semiconductor packages to be tested are placed, or to place a tested semiconductor package into a second customer tray; a tester unit to test the semiconductor package loaded from the loader unit and to unload the tested semiconductor package back to the loader unit; and a shuttle unit installed to connect the loader unit and the tester unit, and to transfer the semiconductor package to either the tester unit or the loader unit.

According to one embodiment of the present disclosure, the loader unit may include a load picker unit to pick up the semiconductor package from the first customer tray retrieved from a load stacker and transfer it to the shuttle unit, or to pick up the semiconductor package transferred via the shuttle unit and place it into the second customer tray to be stored in an unload stacker.

According to one embodiment of the present disclosure, the load picker unit may include a pair of main gantries formed to extend linearly along both ends of the load stacker and the unload stacker, which are arranged in a row; a load gantry formed to extend in a direction perpendicular to the extension direction of the main gantries, to traverse between the main gantries and to slide along the main gantries; an unload gantry formed to extend in parallel to the load gantry, in a direction perpendicular to the extension direction of the main gantries, to traverse between the main gantries and to slide along the main gantries; a load picker installed to be slidable along the load gantry and to pick up the semiconductor package from the first customer tray and transfer it to the shuttle unit; and an unload picker installed to be slidable along the unload gantry and to pick up the semiconductor package from the shuttle unit and transfer it to the second customer tray.

According to one embodiment of the present disclosure, the load picker unit may further include an unload vision inspection unit installed below the movement path of the unload picker and to perform vision inspection of the exterior of the semiconductor package picked up and transferred by the unload picker.

According to one embodiment of the present disclosure, the unload picker may be configured to correct a pickup error of the semiconductor package based on the result of the vision inspection of the exterior of the semiconductor package by the unload vision inspection unit.

According to one embodiment of the present disclosure, the load picker unit may further include a tray picker installed to be slidable along a tray gantry, and to retrieve the first customer tray from the load stacker or to store the second customer tray into the unload stacker.

According to one embodiment of the present disclosure, the shuttle unit may include a shuttle rail unit formed to extend between the loader unit and the tester unit so as to connect the loader unit and the tester unit; and a shuttle stage installed to be slidable along the shuttle rail unit and to transfer the semiconductor package between the loader unit and the tester unit.

According to one embodiment of the present disclosure, the shuttle unit may further include a flipping unit installed at one end of the shuttle rail unit and to flip the semiconductor package transferred onto the shuttle stage upside down.

According to one embodiment of the present disclosure, the shuttle rail unit may be formed to extend in a direction parallel to the extension direction of the main gantry, so that the shuttle stage can transfer the semiconductor package between the loader unit and the tester unit along a direction parallel to the extension direction of the main gantry, and one end thereof is formed to extend to the tester unit.

According to one embodiment of the present disclosure, the shuttle stage may include a heater unit installed inside the shuttle stage and to heat the semiconductor package placed on the upper surface of the shuttle stage.

According to one embodiment of the present disclosure, the shuttle stage may include a cooling unit including a nozzle installed on a side of the shuttle stage and to blow air toward the semiconductor package placed on the upper surface of the shuttle stage to cool the semiconductor package.

According to one embodiment of the present disclosure, the tester unit may include a tester module to test the semiconductor package; an align picker unit to pick up the semiconductor package transferred to the tester unit via the shuttle unit and place it onto a tester stage for testing, or to pick up the tested semiconductor package from the tester stage and place it onto the shuttle unit; and a tester stage installed to be slidable between the align picker unit and the tester module and to move the semiconductor packages to be tested to a position corresponding to the tester module or move the tested semiconductor packages to a position corresponding to the align picker unit.

According to one embodiment of the present disclosure, the align picker unit may include an align gantry formed to extend linearly between one end of the shuttle unit and a position corresponding to the sliding movement path of the tester stage; and an align picker installed to be slidable along the align gantry, and to pick up the semiconductor package transferred via the shuttle unit and place it onto the tester stage, or pick up the tested semiconductor package from the tester stage and place it onto the shuttle unit.

According to one embodiment of the present disclosure, the align picker may include a hollow portion formed to penetrate the align picker in its height direction.

According to one embodiment of the present disclosure, the align picker unit may further include an align vision inspection unit installed above the align picker, and to inspect the internal pattern on the upper surface of the semiconductor package picked up by the align picker through the hollow portion.

According to one embodiment of the present disclosure, the align picker may be configured to correct a pickup error of the semiconductor package based on a result of the vision inspection of the internal pattern of the semiconductor package by the align vision inspection unit.

According to one embodiment of the present disclosure, the align picker unit may be configured to pre-calculate and store deformation data corresponding to deformation amounts of the tester stage at different temperatures, and upon placing the semiconductor package on the tester stage, calculates the real-time deformation amount of the tester stage based on the measured real-time temperature of the tester stage and the deformation data, and places the semiconductor package on the tester stage by offsetting the placing position according to the calculated real-time deformation amount.

According to one embodiment of the present disclosure, the tester unit may further include an upper vision inspection device installed above the movement path of the tester stage and to check the arrangement state of the semiconductor packages placed in rows and columns on the tester stage.

According to one embodiment of the present disclosure, method of testing a semiconductor package using a test handler is provided. The test handler may include a loader unit to pick up a semiconductor package from a first customer tray in which semiconductor packages to be tested are placed or to place a tested semiconductor package into a second customer tray, a tester unit to test the semiconductor package loaded from the loader unit and to unload the tested semiconductor package back to the loader unit, and a shuttle unit installed to connect the loader unit and the tester unit and to transfer the semiconductor package to either the tester unit or the loader unit,

According to one embodiment of the present disclosure, the method may include the steps of: (a) retrieving the first customer tray from a load stacker; (b) picking up the semiconductor package from the first customer tray by a load picker; (c) placing the semiconductor package onto a shuttle stage of the shuttle unit; (d) transferring the semiconductor package to the tester unit via the shuttle stage; (e) picking up the semiconductor package by an align picker unit of the tester unit and placing it onto a tester stage; (f) moving the tester stage with the placed semiconductor packages to a position corresponding to a tester module; (g) electrically contacting the tester module with the semiconductor packages placed on the tester stage to perform testing; (h) moving the tester stage with the tested semiconductor packages to a position corresponding to the align picker unit; (i) picking up the tested semiconductor packages from the tester stage by the align picker unit and placing them onto the shuttle stage; (j) picking up the tested semiconductor packages placed on the shuttle stage by an unload picker and placing them into the second customer tray; and (k) storing the second customer tray containing the tested semiconductor packages into an unload stacker.

According to one embodiment of the present disclosure, a test handler is provided. The test handler may include a loader unit to pick up a semiconductor package from a first customer tray in which semiconductor packages to be tested are placed or to place a tested semiconductor package into a second customer tray; a tester unit to test the semiconductor package loaded from the loader unit and to unload the tested semiconductor package back to the loader unit; and a shuttle unit installed to connect the loader unit and the tester unit and to transfer the semiconductor package to either the tester unit or the loader unit. The loader unit may include a load picker unit to pick up the semiconductor package from the first customer tray retrieved from a load stacker and transfer it to the shuttle unit, or to pick up the semiconductor package transferred via the shuttle unit and place it into the second customer tray to be stored in an unload stacker. The load picker unit may include a pair of main gantries formed to extend linearly along both ends of the load stacker and the unload stacker; a load gantry formed to extend in a direction perpendicular to the extension direction of the main gantries, to traverse between the main gantries and to slide along the main gantries; an unload gantry formed in parallel with the load gantry to extend in a direction perpendicular to the extension direction of the main gantries, to traverse between the main gantries and to slide along the main gantries; a load picker installed to be slidable along the load gantry and to pick up the semiconductor package from the first customer tray and transfer it to the shuttle unit; an unload picker installed to be slidable along the unload gantry and to pick up the semiconductor package from the shuttle unit and transfer it to the second customer tray; and an unload vision inspection unit installed below the movement path of the unload picker and to perform vision inspection of the exterior of the semiconductor package picked up and transferred by the unload picker. The unload picker is configured to correct a pickup error of the semiconductor package based on a result of the vision inspection of the semiconductor package exterior by the unload vision inspection unit. The shuttle unit may include a shuttle rail unit formed to extend between the loader unit and the tester unit; and a shuttle stage installed to be slidable along the shuttle rail unit and to transfer the semiconductor package between the loader unit and the tester unit. The shuttle stage may include a heater unit installed inside the shuttle stage and to heat the semiconductor package placed on its upper surface; and a cooling unit including a nozzle installed on a side of the shuttle stage and to blow air toward the semiconductor package placed on its upper surface to cool the semiconductor package. The tester unit may include a tester module to test the semiconductor package; an align picker unit to pick up the semiconductor package transferred to the tester unit via the shuttle unit and place it onto a tester stage for testing, or to pick up the tested semiconductor package from the tester stage and place it onto the shuttle unit; and a tester stage installed to be slidable between the align picker unit and the tester module and to move the semiconductor packages to be tested to a position corresponding to the tester module or to move the tested semiconductor packages to a position corresponding to the align picker unit. The align picker unit may include an align gantry formed to extend linearly between one end of the shuttle unit and a position corresponding to the sliding movement path of the tester stage; an align picker installed to be slidable along the align gantry and to pick up the semiconductor package transferred via the shuttle unit and place it onto the tester stage, or to pick up the tested semiconductor package from the tester stage and place it onto the shuttle unit; and an align vision inspection unit installed above the align picker having a hollow portion, and to inspect the internal pattern on the upper surface of the semiconductor package picked up by the align picker through the hollow portion. The align picker is configured to correct a pickup error of the semiconductor package based on a result of the vision inspection of the internal pattern of the semiconductor package by the align vision inspection unit. The align picker unit is configured to pre-calculate and store deformation data corresponding to deformation amounts of the tester stage at different temperatures, and upon placing the semiconductor package on the tester stage, calculates the real-time deformation amount of the tester stage based on the measured real-time temperature of the tester stage and the deformation data, and places the semiconductor package on the tester stage by offsetting the placing position according to the calculated real-time deformation amount.

### BRIEF DESCRIPTION OF THE DRAWINGS

The above and other features and advantages of the present invention will become more apparent by describing in detail embodiments thereof with reference to the attached drawings in which:

FIG. 1 is a schematic diagram showing the configuration of a test handler according to one embodiment of the present disclosure.

FIGS. 2 and 3 are schematic diagrams showing the configuration of a load picker unit of the test handler in FIG. 1.

FIG. 4 is a schematic diagram showing the configuration of a shuttle unit of the test handler in FIG. 1.

FIG. 5 is a schematic diagram showing the configuration of an align picker unit of the test handler in FIG. 1.

FIG. 6 is a schematic diagram showing the configuration of a test handler according to another embodiment of the present disclosure.

FIG. 7 is a flowchart sequentially illustrating a semiconductor package inspection method according to another embodiment of the present disclosure.

### DETAILED DESCRIPTION OF THE INVENTION

Hereinafter, preferred embodiments of the present disclosure will be described in detail with reference to the accompanying drawings.

The embodiments of the present disclosure are provided to more fully convey the concept of the disclosure to those skilled in the art. The following embodiments may be modified in various forms, and the scope of the present disclosure is not limited to these embodiments. Rather, the embodiments are provided to ensure thorough and complete disclosure of the disclosure, and to fully convey the scope of the disclosure to those skilled in the art. In addition, the thicknesses or sizes of the respective layers illustrated in the drawings are exaggerated for the sake of clarity and ease of understanding.

The embodiments of the present disclosure are described below with reference to the accompanying drawings, which schematically show ideal examples of the disclosure. Variations from the illustrated shapes may be anticipated due to, for example, manufacturing technology and/or tolerances. Therefore, the implementation of the disclosure should not be interpreted as being limited to the specific shapes shown in the specification, but should include shape variations that may arise in actual manufacturing.

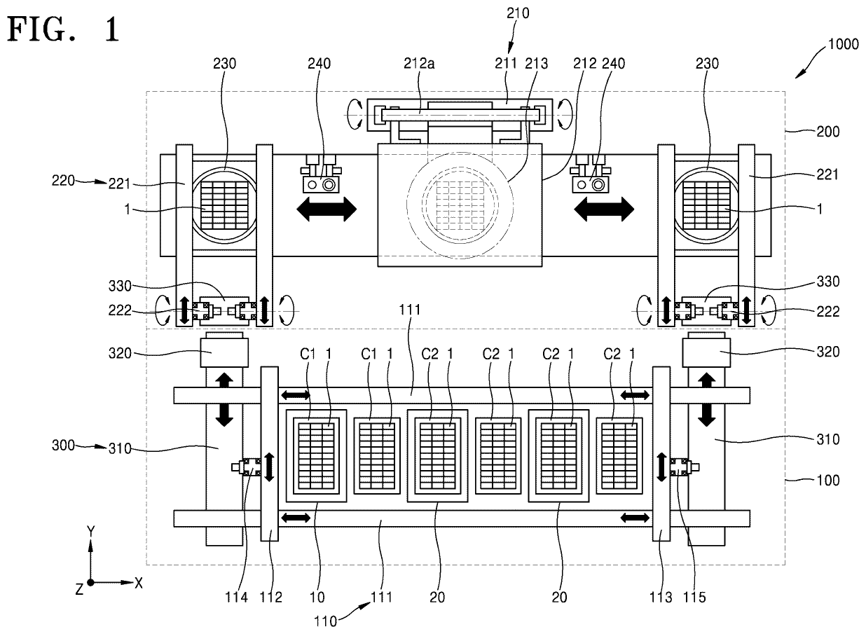

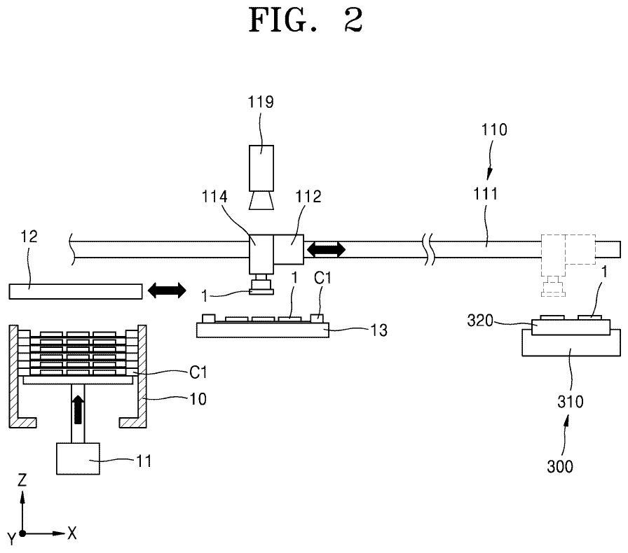

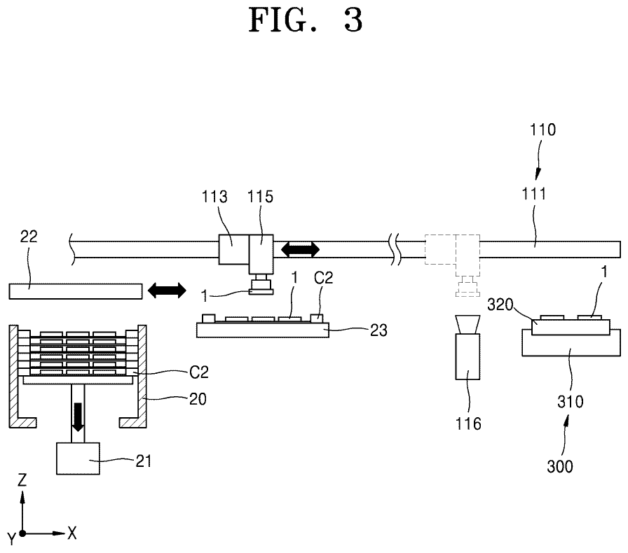

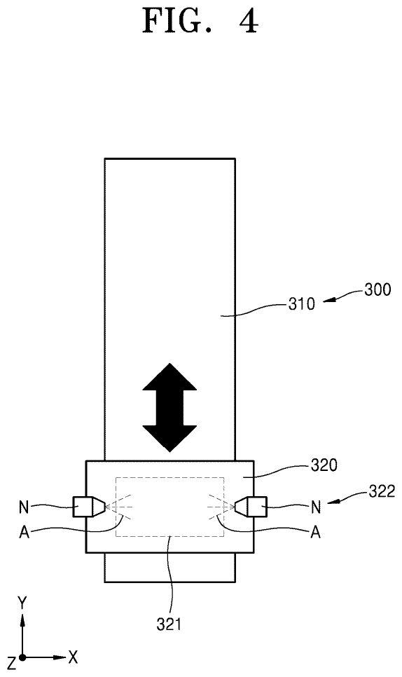

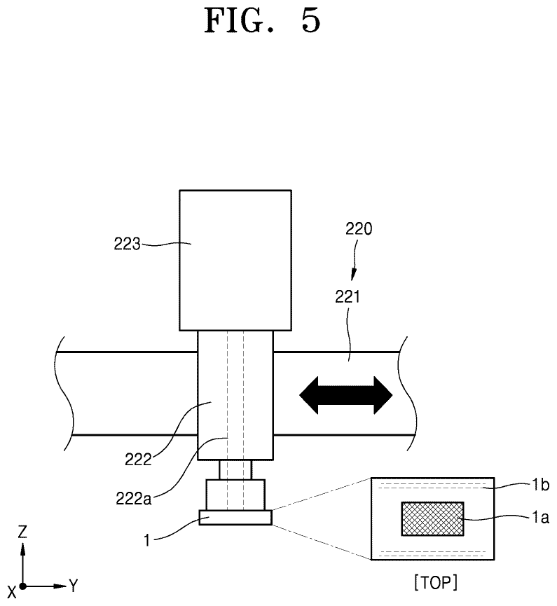

FIG. 1 is a schematic diagram showing the configuration of a test handler 1000 according to an embodiment of the present disclosure. FIGS. 2 and 3 are schematic diagrams showing the configuration of the load picker unit 110 of the test handler 1000 in FIG. 1. FIG. 4 is a schematic diagram showing the configuration of the shuttle unit 300 of the test handler 1000 in FIG. 1. FIG. 5 is a schematic diagram showing the configuration of the align picker unit 220 of the test handler 1000 in FIG. 1.

As shown in FIG. 1, the test handler 1000 according to one embodiment of the present disclosure may largely include a loader unit 100, a tester unit 200, and a shuttle unit 300.

As shown in FIG. 1, the loader unit 100 is to pick up a semiconductor package 1 from a first customer tray C1, on which semiconductor packages 1 to be tested by the tester unit 200 are placed, or to place a semiconductor package 1 that has been tested by the tester unit 200 onto a second customer tray C2.

Here, the second customer tray C2, on which the tested semiconductor package 1 is to be placed, may be either a reused first customer tray C1 from which the semiconductor package 1 was picked up by the loader unit 100, or a new customer tray.

Additionally, the second customer tray C2 may preferably be provided in at least two units in the loader unit 100, so that the tested semiconductor packages 1 can be placed separately as non-defective or defective based on the inspection results from the tester unit 200. Accordingly, the unload stacker 20, into which the second customer tray C2 is stored, may also be provided in at least two units.

As shown in FIGS. 1 through 3, the load picker unit 110 of the loader unit 100 is to pick up a semiconductor package 1 from the first customer tray C1 extracted from the load stacker 10 and transfer it to the shuttle stage 320 of the shuttle unit 300, or to pick up a semiconductor package 1 transferred to the shuttle unit 300 from the shuttle stage 320 and place it onto the second customer tray C2, which is to be stored in the unload stacker 20.

For example, the load picker unit 110 may include a main gantry 111 formed to extend horizontally (in the X-axis direction) along both ends of the load stacker 10 and the unload stacker 20, which are arranged side by side in a row. The load picker unit 110 may include a load gantry 112 formed to extend in a direction (Y-axis direction) perpendicular to the extension direction (X-axis direction) of the main gantry 111, crossing between the main gantry 111, and to slide in the horizontal direction (X-axis direction) along the main gantry 111. The load picker unit 110 may include an unload gantry 113 formed to extend parallel to the load gantry 112 in the Y-axis direction and perpendicular to the main gantry 111 in the X-axis direction, crossing between the main gantry 111 and to slide along the main gantry 111 in the X-axis direction. In this manner, the main gantry 111, the load gantry 112, and the unload gantry 113 may be formed to have an overall “#” (well-shaped) structure when viewed from above the test handler 1000 (as shown in FIG. 1).

Additionally, as shown in FIGS. 1 and 2, the load picker unit 110 may include a load picker 114 installed to be slidable in the vertical direction (Y-axis direction) along the load gantry 112 and a load vision inspection unit 119. The load picker 114 is to pick up a semiconductor package 1 from the first customer tray C1 and place the picked-up semiconductor package 1 onto the shuttle stage 320 of the shuttle unit 300 by sliding in the vertical direction (Y-axis direction) along the load gantry 112 and in the horizontal direction (X-axis direction) along the same. The load vision inspection unit 119 is to perform a vision inspection on the exterior of the semiconductor package 1 being picked up by the load picker 114.

As shown in FIG. 2, the first customer tray C1 may be extracted from the load stacker 10 and positioned on the first customer stage 13.

More specifically, the elevator 11 of the load stacker 10 lifts the first customer trays C1, which are stacked inside the load stacker 10, in the height direction (Z-axis direction), and raises the uppermost first customer tray C1 to the top of the load stacker 10. Accordingly, a loading transfer arm 12, located above the load stacker 10, transfers the uppermost first customer tray C1 from the load stacker 10 to the first customer stage 13.

Furthermore, as shown in FIGS. 1 and 3, the load picker unit 110 may also include an unload picker 115 installed to be slidable in the vertical direction (Y-axis direction) along the unload gantry 113. The unload picker 115 is to pick up a semiconductor package 1 from the shuttle stage 320 of the shuttle unit 300 and place the picked-up semiconductor package 1 onto the second customer tray C2 by sliding in the vertical direction (Y-axis direction) and in the horizontal direction (X-axis direction) along the unload gantry 113.

As shown in FIG. 3, the second customer tray C2 is positioned on the second customer stage 23, and once the placing of the tested semiconductor package 1 is completed, the second customer tray C2 may be stored into the unload stacker 20.

More specifically, the elevator 21 of the unload stacker 20 lowers the second customer trays C2, which are stacked inside the unload stacker 20, in the height direction (Z-axis direction), and positions the uppermost second customer tray C2 one tray-height below the top of the unload stacker 20. Accordingly, an unloading transfer arm 22 located above the unload stacker 20 transfers the second customer tray C2 positioned on the second customer stage 23 into the unload stacker 20.

Additionally, the load picker unit 110 may further include an unload vision inspection unit 116 installed below the unload picker 115 along the travel path of the unload picker 115. The unload vision inspection unit 116 is to perform a vision inspection on the exterior of the semiconductor package 1 being picked up and transferred by the unload picker 115.

For example, the unload vision inspection unit 116, located below the unload picker 115, captures the bottom surface of the semiconductor package 1 picked up and transferred by the unload picker 115. Based on the outer surface (edge portion) of the captured semiconductor package 1, the pickup position of the semiconductor package 1 picked up by the unload picker 115 can be identified, thereby detecting any positional errors of the pickup position (errors in the X-axis or Y-axis directions relative to the target pickup position, or rotational errors with respect to the Z-axis).

Accordingly, the unload picker 115 may correct the pickup error of the semiconductor package 1 based on the result of the vision inspection performed by the unload vision inspection unit 116 on the exterior of the semiconductor package 1. Then, by offsetting the corrected amount from the target placing position on the second customer tray C2, the unload picker 115 can accurately place the semiconductor package 1 onto the second customer tray C2.

As illustrated in FIGS. 1 and 4, the shuttle unit 300 is installed to extend vertically (in the Y-axis direction) so as to connect the loader unit 100 and the tester unit 200 described below. The shuttle unit 300 transfers the semiconductor package 1 to either the tester unit 200 or the loader unit 100, and can preheat or cool the semiconductor package 1 during transfer.

For instance, the shuttle rail unit 310 of the shuttle unit 300 is formed to extend in the Y-axis direction, which is perpendicular to the extension direction of the pair of main gantries 111 that are arranged in parallel. One end of the shuttle rail unit 310, directed toward the tester unit 200, may be formed to extend to the range of movement of the align picker unit 220 of the tester unit 200.

Further, the shuttle stage 320 of the shuttle unit 300 is installed to be slidable along the shuttle rail unit 310, enabling transfer of the semiconductor package 1 between the loader unit 100 and the tester unit 200.

The shuttle stage 320 may be to preheat or cool the semiconductor package 1 placed thereon during transfer to a temperature suitable for testing. The shuttle stage 320 may include a heater unit 321, installed inside the shuttle stage 320, which heats the semiconductor package 1 placed on the upper surface of the shuttle stage 320 before testing to a preset test temperature. The shuttle stage 320 may include a cooling unit 322, which includes a nozzle N installed on the side of the shuttle stage 320 to blow air (A) toward the semiconductor package 1 after testing to cool the tested semiconductor package 1 to room temperature.

Additionally, the flipping unit 330 of the shuttle unit 300 is installed at one end of the shuttle rail unit 310 and is to flip the semiconductor package 1, which is transferred toward the tester unit 200 via the shuttle stage 320, upside down.

For example, the semiconductor package 1 stored in the first customer tray C1 may be positioned such that the surface on which the micro pillar bumps (1a in FIG. 5) and pads (1b in FIG. 5) are formed faces downward. Accordingly, in order to facilitate accurate electrical characteristic testing in the tester unit 200, the flipping unit 330 may flip the semiconductor package 1 upside down so that the surface with the micro pillar bumps 1a and pads 1b faces upward before testing.

Conversely, after the testing of the semiconductor package 1 is completed in the tester unit 200, the flipping unit 330 may again flip the tested semiconductor package 1 upside down so that the surface with the micro pillar bumps 1a and pads 1b faces downward, thereby enabling the semiconductor package 1 to be stored in the second customer tray C2 in a proper orientation.

As illustrated in FIG. 1, the tester unit 200 is to test the semiconductor package 1 loaded from the loader unit 100 and to unload the tested semiconductor package 1 back to the loader unit 100.

For example, the tester module 210 of the tester unit 200 is capable of testing the semiconductor package 1.

More specifically, the tester module 210 may include a tester main body 211 positioned on one side of the sliding movement path of the tester stage 230 (to be described later). The tester module 210 may include a tester 212 rotatably installed on the tester main body 211 via a hinge shaft 212a so as to be selectively positioned above the tester stage 230 along the sliding movement path of the tester stage 230, and to provide test signals for electrically testing the semiconductor package 1. The tester module 210 may include a probe module 213 slidably installed in the tester main body 211 in the forward and backward direction toward the sliding movement path of the tester stage 230 so as to be selectively positioned between the tester 212 and the tester stage 230, for electrically connecting the tester 212 with the semiconductor package 1 placed on the tester stage 230.

Accordingly, the tester 212 is electrically connected to the semiconductor package 1 placed on the tester stage 230 via the above-described probe module 213 to provide electrical signals to the semiconductor package 1. The tester 212 analyzes output signals from the semiconductor package 1 to determine whether the semiconductor package 1 placed on the tester stage 230 is acceptable or defective.

Further, as illustrated in FIGS. 1 and 5, the align picker unit 220 of the tester unit 200 picks up the vertically flipped semiconductor package 1, which is transferred to the tester unit 200 via the shuttle unit 300, from the flipping unit 330 and places it onto the tester stage 230 for testing. After the test is completed, the align picker unit 220 picks up the semiconductor package 1 from the tester stage 230 and places it onto the flipping unit 330 so that the package can be flipped again and transferred back toward the loader unit 100.

For example, the align gantry 221 of the align picker unit 220 may be formed to extend linearly in the vertical direction (Y-axis direction) between the flipping unit 330 formed at one end of the shuttle unit 300 and a position corresponding to the sliding movement path of the tester stage 230.

In addition, the align picker 222 of the align picker unit 220 is installed to be slidable in the vertical direction (Y-axis direction) along the align gantry 221, and may pick up the vertically flipped semiconductor package 1, which is transferred via the shuttle unit 300, from the flipping unit 330 and place it onto the tester stage 230. After the test is completed, the align picker 222 may pick up the semiconductor package 1 from the tester stage 230, and after it is flipped again, place it onto the flipping unit 330 of the shuttle unit 300 for transfer back toward the loader unit 100.

Additionally, the align vision inspection unit 223 of the align picker unit 220 is installed above the align picker 222, which has a hollow portion 222a, and is to perform vision inspection of the internal pattern on the upper surface of the semiconductor package 1 picked up by the align picker 222 through the hollow portion 222a.

For example, the align vision inspection unit 223 captures the upper surface of the semiconductor package 1, which is picked up and transferred by the align picker 222, through the hollow portion 222a formed to penetrate the align picker 222 in the height direction (Z-axis direction) from above the align picker 222. Based on the internal pattern of the upper surface of the semiconductor package 1, where micro pillar bumps 1a and pads 1b are formed, the pickup position of the semiconductor package 1 picked up by the align picker 222 can be determined, thereby identifying any pickup errors (errors in the X-axis or Y-axis directions or rotational errors with respect to the Z-axis).

Accordingly, the align picker 222 can correct the pickup error of the semiconductor package 1 based on the vision inspection result of the internal pattern of the semiconductor package 1 provided by the align vision inspection unit 223. By offsetting the semiconductor package 1 by the amount of pickup error from the target placing position on the tester stage 230 (the test position where the probe of the probe module 213 can be accurately connected to the pad 1b of the semiconductor package 1), the align picker 222 can precisely perform the placing operation onto the tester stage 230, thereby enabling the tester module 210 to conduct a precise test on the semiconductor package 1.

Further, as illustrated in FIG. 1, the tester stage 230 of the tester unit 200 is installed to be slidable between the align picker unit 220 and the tester module 210, so that it can move the semiconductor packages 1 to be tested to the position corresponding to the tester module 210, or move the tested semiconductor packages 1 to the position corresponding to the align picker unit 220.

The tester stage 230 functions as a type of chuck that supports the semiconductor package 1 to be tested in the tester module 210. To accommodate various parameters, the tester stage 230 may be a chuck with a multi-parameter structure that allows for temperature control by region.

Additionally, the tester stage 230 may undergo deformation, such as expansion or contraction, depending on its temperature. As a result of such deformation, even if the align picker 222 places the semiconductor package 1 at the target placing position, a positional error may still occur due to the deformation of the tester stage 230.

Accordingly, the align picker unit 220 may pre-calculate and store deformation data corresponding to the amount of deformation of the tester stage 230 at various temperatures. When the align picker unit 220 places the semiconductor package 1 onto the tester stage 230, it calculates the real-time deformation amount of the tester stage 230 based on the measured real-time temperature of the tester stage 230 and the stored deformation data. Then, it offsets the placing position of the semiconductor package 1 by the calculated real-time deformation amount, thereby preventing placing position errors caused by deformation of the tester stage 230.

Furthermore, as illustrated in FIG. 1, the tester unit 200 may include two tester stages 230 that are arranged symmetrically in the horizontal direction (X-axis direction) with respect to the tester module 210.

Accordingly, while one tester stage 230 moves to the tester module 210 for performing the testing process on the semiconductor package 1, the other tester stage 230 moves to the align picker unit 220 to transfer the tested semiconductor package 1 toward the loader unit 100 via the shuttle unit 300. Simultaneously, it receives a new semiconductor package 1, which is to be tested, from the loader unit 100 via the shuttle unit 300. By handling the logistics of the semiconductor packages 1 in this manner, the testing time of the semiconductor package 1 in the test handler 1000 can be reduced.

To accommodate the dual-structure tester stages 230, the align picker unit 220 and the shuttle unit 300, as illustrated in FIG. 1, may also be formed in a dual structure with two units arranged symmetrically in the horizontal direction (X-axis direction) with respect to the tester module 210.

In addition, an upper vision inspection device 240 may be installed above the movement path of the tester stage 230. During the movement of the tester stage 230 toward the tester module 210, the upper vision inspection device 240 checks the arrangement state of the semiconductor packages 1 placed in multiple rows and columns on the tester stage 230, and may rotate the tester stage 230 to perform alignment.

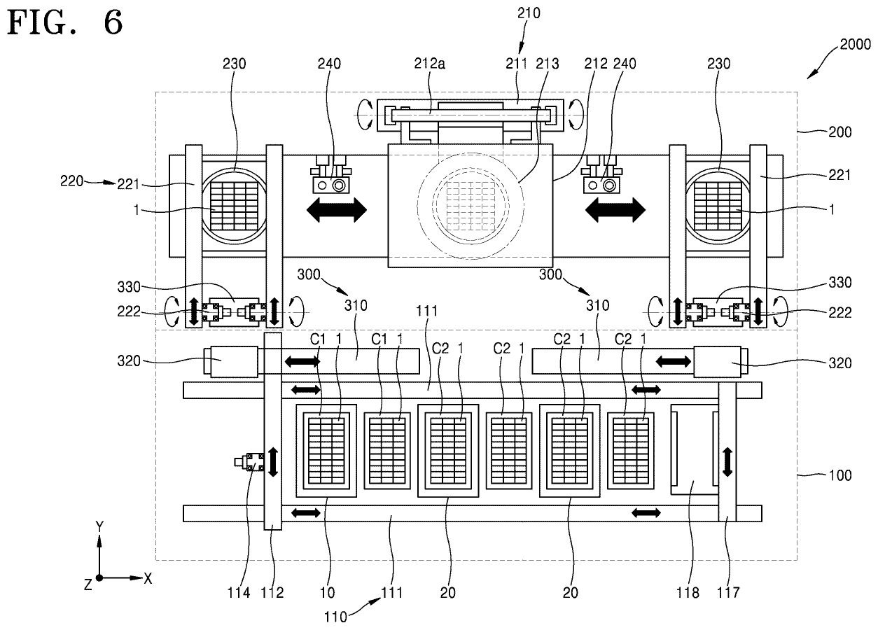

FIG. 6 is a schematic diagram schematically illustrating the configuration of a test handler 2000 according to another embodiment of the present invention.

The layout of the loader unit 100 and the shuttle unit 300, which respectively load the semiconductor package 1 to be tested into the tester unit 200 or unload the tested semiconductor package 1, is not necessarily limited to that shown in FIG. 1. It may be configured in a variety of forms depending on the space available for equipment installation.

For example, as illustrated in FIG. 6, the load picker unit 110 of the loader unit 100 includes: a pair of main gantries 111 formed to extend linearly and horizontally in the X-axis direction along both ends of the load stacker 10 and the unload stacker 20, which are arranged side by side in a row; a load/unload gantry 112, which is formed to extend in the vertical direction (Y-axis direction) perpendicular to the extension direction (X-axis direction) of the main gantries 111, so as to traverse between the main gantries 111, and is to slide along the main gantries 111 in the horizontal direction (X-axis direction); and a tray gantry 117, which is also formed to extend in the vertical direction (Y-axis direction), perpendicular to the extension direction (X-axis direction) of the main gantries 111, so as to traverse between the main gantries 111, and is to slide along the main gantries 111 in the horizontal direction (X-axis direction), in parallel with the load/unload gantry 112 in the Y-axis direction. Accordingly, the main gantries 111, the load/unload gantry 112, and the tray gantry 117 may be to form an overall “#”-shaped (well-shaped) structure when viewed from above the test handler 2000, as shown in FIG. 6.

In this case, the load picker unit 110 includes a load/unload picker 114, which is installed to be slidable in the vertical direction (Y-axis direction) along the load/unload gantry 112. The load/unload picker 114 picks up the semiconductor package 1 to be tested from the first customer tray C1 and places it onto the shuttle stage 320 of the shuttle unit 300, or picks up the tested semiconductor package 1 from the shuttle stage 320 of the shuttle unit 300 and places it onto the second customer tray C2. The load picker unit 110 may further include a tray picker 118, which is installed to be slidable in the vertical direction (Y-axis direction) along the tray gantry 117. The tray picker 118 is to retrieve the first customer tray C1 containing the semiconductor package 1 to be tested from the load stacker 10 or to store the second customer tray C2 containing the tested semiconductor package 1 into the unload stacker 20.

Also, as illustrated in FIG. 6, the shuttle unit 300 is installed to extend in the horizontal direction (X-axis direction), parallel to the main gantry 111, to connect the loader unit 100 and the tester unit 200. It transfers the semiconductor package 1 to the tester unit 200 or back to the loader unit 100 and is capable of preheating or cooling the semiconductor package 1 during transfer.

For example, the shuttle rail unit 310 of the shuttle unit 300 is formed to extend in the horizontal direction (X-axis direction), parallel to the extension direction of the pair of main gantries 111. One end of the shuttle rail unit 310, directed toward the tester unit 200, is extended to reach the operating range of the align picker unit 220 of the tester unit 200, allowing for perpendicular interfacing with the align picker unit 220.

Accordingly, the shuttle stage 320 of the shuttle unit 300 is installed to be slidable in the horizontal direction (X-axis direction) along the shuttle rail unit 310, and can transport the semiconductor package 1 between the loader unit 100 and the tester unit 200.

By forming the shuttle unit 300 to extend in the horizontal direction (X-axis direction) parallel to the extension direction of the main gantry 111, the overall layout of the equipment can be optimized, thereby reducing the footprint of the test handler 2000.

Additionally, the shuttle stage 320 of the shuttle unit 300 may be installed to be movable in the vertical direction (Z-axis direction) on the shuttle rail unit 310. Through upward or downward movement, the shuttle stage 320 may stack multiple layers of semiconductor packages 1 in the vertical direction (Z-axis direction) during transfer, thereby increasing the transfer efficiency of the semiconductor packages 1.

Hereinafter, a specific description will be provided regarding the semiconductor package testing method using the above-described test handler 1000.

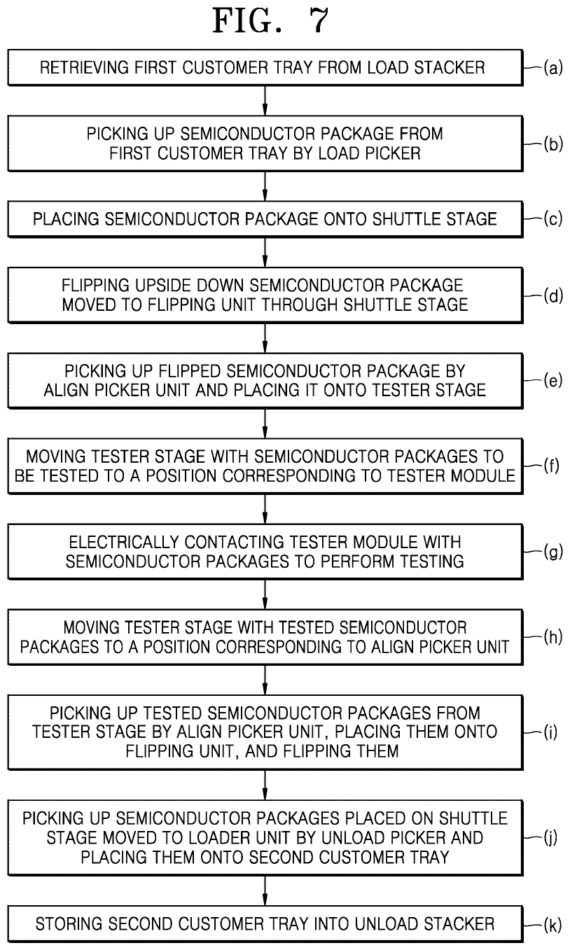

FIG. 7 is a flowchart sequentially illustrating a semiconductor package inspection method according to another embodiment of the present disclosure.

As shown in FIG. 7, the semiconductor package testing method according to another embodiment of the present disclosure may include the following steps of (a) retrieving the first customer tray C1 from the load stacker 10, (b) picking up the semiconductor package 1 from the first customer tray C1 by the load picker 114, (c) placing the semiconductor package 1 onto the shuttle stage 320 of the shuttle unit 300, (d) flipping the semiconductor package 1 upside down at the flipping unit 330 formed at one end of the shuttle rail unit 310, (e) picking up the vertically flipped semiconductor package 1 by the align picker unit 220 of the tester unit 200 and placing it onto the tester stage 230, (f) moving the tester stage 230, with the semiconductor packages 1 placed thereon, to a position corresponding to the tester module 210, (g) electrically contacting the tester module 210 with the semiconductor packages 1 placed on the tester stage 230 to perform testing, (h) moving the tester stage 230, with the tested semiconductor packages 1 placed thereon, to a position corresponding to the align picker unit 220, (i) picking up the tested semiconductor packages 1 from the tester stage 230 by the align picker unit 220, placing them onto the flipping unit 330, and flipping them again, (j) picking up the semiconductor packages 1, now placed on the shuttle stage 320 moved to the loader unit 100 by the unload picker 115 and placing them onto the second customer tray C2, and (k) storing the second customer tray C2, in which the tested semiconductor packages 1 are placed, into the unload stacker 20.

Accordingly, according to various embodiments of the present disclosure, the test handler 1000 and the semiconductor package testing method can serve as an electrical inspection system for semiconductor packages (HBM chips) 1 having micro pillar bumps. After performing an electrical inspection process on the semiconductor packages 1 loaded in the first customer tray C1, the semiconductor packages can be re-attached to a second customer tray C2 according to the determination of whether they are non-defective or defective.

Additionally, the tester stage 230, on which the semiconductor package 1 is placed to perform the electrical inspection process, is as an individual chucking device with a multi-parameter (multi-Para) structure capable of accommodating various parameters (including dual chuck configuration). This allows for precise hot/cold temperature control of the chuck. Depending on the deformation amount of the chuck at specific temperatures (such as low, room, or high temperature), the align picker unit 220 can apply an offset to the placing position of the semiconductor package 1 on the chuck. As a result, the placing position of the semiconductor package 1 can be precisely adjusted to compensate for chuck deformation at each temperature level.

Additionally, by implementing the align picker unit 220 as an align picker 222 having a hollow structure, the align vision inspection unit 223 installed above the align picker 222 can inspect the internal pattern on the upper surface of the semiconductor package 1 picked up by the align picker 222 through the hollow portion 222a. This allows for correction of pickup errors. Furthermore, the unload vision inspection unit 116, which is installed below the movement path of the unload picker 115 that returns the inspected semiconductor package 1 to the second customer tray C2, performs vision inspection of the lower surface (exterior) of the semiconductor package 1 picked up by the unload picker 115, thereby correcting pickup errors. Through this vision-based approach, precise alignment technology for the semiconductor package 1 can be implemented, and the accuracy of the semiconductor package inspection process can be further improved.

Accordingly, a test handler 1000 and a semiconductor package testing method capable of precisely classifying the condition of high bandwidth memory (HBM) devices—each formed by stacking multiple memory and logic dies—can be realized. The HBM devices can be accurately positioned and subjected to electrical inspection, thereby enhancing the testing precision and improving the determination of whether the HBM devices are acceptable or defective.

Although the present disclosure has been described with reference to the embodiments illustrated in the drawings, these embodiments are merely exemplary, and various modifications and equivalent alternatives may be devised by those skilled in the art without departing from the scope of the disclosure. Therefore, the true scope of protection of the present disclosure should be defined by the technical spirit described in the appended claims.

What is claimed is:

1. A test handler comprising:
a loader unit to pick up a semiconductor package from a first customer tray in which semiconductor packages to be tested are placed, or to place a tested semiconductor package into a second customer tray;
a tester unit to test the semiconductor package loaded from the loader unit and to unload the tested semiconductor package back to the loader unit; and
a shuttle unit installed to connect the loader unit and the tester unit, and to transfer the semiconductor package to either the tester unit or the loader unit.

2. The test handler of claim 1, wherein the loader unit comprises
a load picker unit to pick up the semiconductor package from the first customer tray retrieved from a load stacker and transfer it to the shuttle unit, or to pick up the semiconductor package transferred via the shuttle unit and place it into the second customer tray to be stored in an unload stacker.

3. The test handler of claim 2, wherein the load picker unit comprises
a pair of main gantries formed to extend linearly along both ends of the load stacker and the unload stacker, which are arranged in a row;
a load gantry formed to extend in a direction perpendicular to the extension direction of the main gantries, to traverse between the main gantries and to slide along the main gantries;
an unload gantry formed to extend in parallel to the load gantry, in a direction perpendicular to the extension direction of the main gantries, to traverse between the main gantries and to slide along the main gantries;
a load picker installed to be slidable along the load gantry and to pick up the semiconductor package from the first customer tray and transfer it to the shuttle unit; and
an unload picker installed to be slidable along the unload gantry and to pick up the semiconductor package from the shuttle unit and transfer it to the second customer tray.

4. The test handler of claim 3, wherein the load picker unit further comprises
an unload vision inspection unit installed below the movement path of the unload picker and to perform vision inspection of the exterior of the semiconductor package picked up and transferred by the unload picker.

5. The test handler of claim 4, wherein the unload picker is configured to correct a pickup error of the semiconductor package based on the result of the vision inspection of the exterior of the semiconductor package by the unload vision inspection unit.

6. The test handler of claim 3, wherein the load picker unit further comprises a tray picker installed to be slidable along a tray gantry, and to retrieve the first customer tray from the load stacker or to store the second customer tray into the unload stacker.

7. The test handler of claim 3, wherein the shuttle unit comprises
a shuttle rail unit formed to extend between the loader unit and the tester unit so as to connect the loader unit and the tester unit; and
a shuttle stage installed to be slidable along the shuttle rail unit and to transfer the semiconductor package between the loader unit and the tester unit.

8. The test handler of claim 7, wherein the shuttle unit further comprises a flipping unit installed at one end of the shuttle rail unit and to flip the semiconductor package transferred onto the shuttle stage upside down.

9. The test handler of claim 7, wherein the shuttle rail unit is formed to extend in a direction parallel to the extension direction of the main gantry, so that the shuttle stage can transfer the semiconductor package between the loader unit and the tester unit along a direction parallel to the extension direction of the main gantry, and one end thereof is formed to extend to the tester unit.

10. The test handler of claim 7, wherein the shuttle stage comprises a heater unit installed inside the shuttle stage and to heat the semiconductor package placed on the upper surface of the shuttle stage.

11. The test handler of claim 7, wherein the shuttle stage comprises a cooling unit including a nozzle installed on a side of the shuttle stage and to blow air toward the semiconductor package placed on the upper surface of the shuttle stage to cool the semiconductor package.

12. The test handler of claim 1, wherein the tester unit comprises
a tester module to test the semiconductor package;
an align picker unit to pick up the semiconductor package transferred to the tester unit via the shuttle unit and place it onto a tester stage for testing, or to pick up the tested semiconductor package from the tester stage and place it onto the shuttle unit; and
the tester stage installed to be slidable between the align picker unit and the tester module and to move the semiconductor packages to be tested to a position corresponding to the tester module or move the tested semiconductor packages to a position corresponding to the align picker unit.

13. The test handler of claim 12, wherein the align picker unit comprises
an align gantry formed to extend linearly between one end of the shuttle unit and a position corresponding to the sliding movement path of the tester stage; and
an align picker installed to be slidable along the align gantry, and to pick up the semiconductor package transferred via the shuttle unit and place it onto the tester stage, or pick up the tested semiconductor package from the tester stage and place it onto the shuttle unit.

14. The test handler of claim 13, wherein the align picker comprises a hollow portion formed to penetrate the align picker in its height direction.

15. The test handler of claim 14, wherein the align picker unit further comprises an align vision inspection unit installed above the align picker, and to inspect the internal pattern on the upper surface of the semiconductor package picked up by the align picker through the hollow portion.

16. The test handler of claim 15, wherein the align picker is configured to correct a pickup error of the semiconductor package based on a result of the vision inspection of the internal pattern of the semiconductor package by the align vision inspection unit.

17. The test handler of claim 16, wherein the align picker unit is configured to pre-calculate and store deformation data corresponding to deformation amounts of the tester stage at different temperatures, and upon placing the semiconductor package on the tester stage, calculates the real-time deformation amount of the tester stage based on the measured real-time temperature of the tester stage and the deformation data, and places the semiconductor package on the tester stage by offsetting the placing position according to the calculated real-time deformation amount.

18. The test handler of claim 12, wherein the tester unit further comprises an upper vision inspection device installed above the movement path of the tester stage and to check the arrangement state of the semiconductor packages placed in rows and columns on the tester stage.

19. A method of testing a semiconductor package using a test handler comprising a loader unit to pick up a semiconductor package from a first customer tray in which semiconductor packages to be tested are placed or to place a tested semiconductor package into a second customer tray, a tester unit to test the semiconductor package loaded from the loader unit and to unload the tested semiconductor package back to the loader unit, and a shuttle unit installed to connect the loader unit and the tester unit and to transfer the semiconductor package to either the tester unit or the loader unit, the method comprising the steps of:
(a) retrieving the first customer tray from a load stacker;
(b) picking up the semiconductor package from the first customer tray by a load picker;
(c) placing the semiconductor package onto a shuttle stage of the shuttle unit;
(d) transferring the semiconductor package to the tester unit via the shuttle stage;
(e) picking up the semiconductor package by an align picker unit of the tester unit and placing it onto a tester stage;
(f) moving the tester stage with the placed semiconductor packages to a position corresponding to a tester module;
(g) electrically contacting the tester module with the semiconductor packages placed on the tester stage to perform testing;
(h) moving the tester stage with the tested semiconductor packages to a position corresponding to the align picker unit;
(i) picking up the tested semiconductor packages from the tester stage by the align picker unit and placing them onto the shuttle stage;
(j) picking up the tested semiconductor packages placed on the shuttle stage by an unload picker and placing them into the second customer tray; and
(k) storing the second customer tray containing the tested semiconductor packages into an unload stacker.

20. A test handler comprising:
a loader unit to pick up a semiconductor package from a first customer tray in which semiconductor packages to be tested are placed or to place a tested semiconductor package into a second customer tray;
a tester unit to test the semiconductor package loaded from the loader unit and to unload the tested semiconductor package back to the loader unit; and
a shuttle unit installed to connect the loader unit and the tester unit and to transfer the semiconductor package to either the tester unit or the loader unit,
wherein the loader unit comprises a load picker unit to pick up the semiconductor package from the first customer tray retrieved from a load stacker and transfer it to the shuttle unit, or to pick up the semiconductor package transferred via the shuttle unit and place it into the second customer tray to be stored in an unload stacker, and
wherein the load picker unit comprises
a pair of main gantries formed to extend linearly along both ends of the load stacker and the unload stacker;
a load gantry formed to extend in a direction perpendicular to the extension direction of the main gantries, to traverse between the main gantries and to slide along the main gantries;
an unload gantry formed in parallel with the load gantry to extend in a direction perpendicular to the extension direction of the main gantries, to traverse between the main gantries and to slide along the main gantries;
a load picker installed to be slidable along the load gantry and to pick up the semiconductor package from the first customer tray and transfer it to the shuttle unit;
an unload picker installed to be slidable along the unload gantry and to pick up the semiconductor package from the shuttle unit and transfer it to the second customer tray; and
an unload vision inspection unit installed below the movement path of the unload picker and to perform vision inspection of the exterior of the semiconductor package picked up and transferred by the unload picker, and
wherein the unload picker is configured to correct a pickup error of the semiconductor package based on a result of the vision inspection of the semiconductor package exterior by the unload vision inspection unit, and
wherein the shuttle unit comprises
a shuttle rail unit formed to extend between the loader unit and the tester unit; and
a shuttle stage installed to be slidable along the shuttle rail unit and to transfer the semiconductor package between the loader unit and the tester unit, and
wherein the shuttle stage comprises
a heater unit installed inside the shuttle stage and to heat the semiconductor package placed on its upper surface; and
a cooling unit including a nozzle installed on a side of the shuttle stage and to blow air toward the semiconductor package placed on its upper surface to cool the semiconductor package, and
wherein the tester unit comprises
a tester module to test the semiconductor package;
an align picker unit to pick up the semiconductor package transferred to the tester unit via the shuttle unit and place it onto a tester stage for testing, or to pick up the tested semiconductor package from the tester stage and place it onto the shuttle unit; and
the tester stage installed to be slidable between the align picker unit and the tester module and to move the semiconductor packages to be tested to a position corresponding to the tester module or to move the tested semiconductor packages to a position corresponding to the align picker unit, and
wherein the align picker unit comprises
an align gantry formed to extend linearly between one end of the shuttle unit and a position corresponding to the sliding movement path of the tester stage;
an align picker installed to be slidable along the align gantry and to pick up the semiconductor package transferred via the shuttle unit and place it onto the tester stage, or to pick up the tested semiconductor package from the tester stage and place it onto the shuttle unit; and
an align vision inspection unit installed above the align picker having a hollow portion, and to inspect the internal pattern on the upper surface of the semiconductor package picked up by the align picker through the hollow portion, and
wherein the align picker is configured to correct a pickup error of the semiconductor package based on a result of the vision inspection of the internal pattern of the semiconductor package by the align vision inspection unit, and
wherein the align picker unit is configured to pre-calculate and store deformation data corresponding to deformation amounts of the tester stage at different temperatures, and upon placing the semiconductor package on the tester stage, calculates the real-time deformation amount of the tester stage based on the measured real-time temperature of the tester stage and the deformation data, and places the semiconductor package on the tester stage by offsetting the placing position according to the calculated real-time deformation amount.
